(19) United States
(12) Patent Application Publication
(10) Pub. No.: US 2002/0121913 A1
(43) Pub. Date: Sep. 5, 2002

(54) Tester with independent control of devices under test

(75) Inventors: R. Mark Miller, Austin, TX (US); Tom Dolbear, Austin, TX (US); Jay Marshall, Austin, TX (US); Paul Hokanson, Bastrop, TX (US)

Correspondence Address: ZAGORIN O'BRIEN & GRAHAM LLP, 401 W 15TH STREET, SUITE 870, AUSTIN, TX, 78701, US

(73) Assignee: Advanced Micro Devices, Inc., Sunnyvale, CA (US)

(21) Appl. No.: 09/750,201

(22) Filed: Dec. 28, 2000

(51) Int. Cl. G01R 31/02

(52) U.S. Cl. 324/760

(57) ABSTRACT

A burn-in tester that provides independent control of the devices under test. The various operating parameters such as temperature, voltage, frequency of operation or test pattern being applied can be independently changed on one device without affecting the operating parameters of the other devices. Thus, e.g., the amount of cooling applied to one device is independent of the amount of cooling applied to another device. In addition, the testing being done on each device may be independently controlled. Thus, a test can be changed on one of the devices under test without affecting the tests being run on any of the other devices. Similarly, the voltage and frequency of operation can be controlled independently to allow for changes to the voltage and/or frequency of one device without affecting those parameters on other devices being tested.

### BACKGROUND OF THE INVENTION

1. Field of the Invention

This invention relates to testing of integrated circuits and more particularly to a tester providing independent control of devices under test.

2. Description of the Related Art

In order to achieve higher reliability, manufacturers frequently employ “burn-in” testing to accelerate potential failure mechanisms. The tests are intended to weed out those parts that may be subject to infant mortality. Manufacturers typically utilize higher than normal supply voltages and temperatures during such tests and lower than normal frequencies. Burn-in testing normally tests the devices over long periods at the higher than normal voltages and temperatures. For some devices, such as current microprocessors (e.g., the Athlon™ microprocessor available from Advanced Micro Devices, Inc.) the large number of transistors results in high power consumption during burn-in testing. That is in part due to the fact that CMOS transistors typically utilized in such microprocessors leak a small amount of current even when “off”. Because of the large number of transistors found in current devices, even if the leakage current of each transistor is small, the cumulative leakage current can be significant. In addition, there is a tendency for the faster parts to have higher leakage currents.

Another problem that is faced when testing high density devices in a burn-in environment is that operating the device at higher voltage and temperatures can result in the device operating in a region in which device operation is unstable. More particularly, the device under test can enter a destructive positive feedback loop in which, as the part heats up, the transistors leak more current, which causes more heat, potentially resulting in thermal runaway. Thermal runaway can result in melting the socket in which the device is being tested, damage to the test board or damage to the device under test.

Many previous burn-in testers utilized air or oil manifolds to drive all the devices under test to the same temperature. Thus, no independent temperature control is possible and only limited action can be taken in response to unstable device operation. Prior art burn-in testers also required that the key parameters, such as voltage frequency or test patterns being applied to the devices under test, be the same for all devices. While that may be sufficient for testing older technologies, it fails to allow the flexibility to test devices according to the unique testing parameters that may be required by the individual devices, especially in current burn-in test environments.

Thus, it would be desirable to provide a tester that allows the key testing parameters to be varied for each device without affecting the other devices under test.

### SUMMARY OF THE INVENTION

Accordingly, the invention provides a tester that provides independent control of the devices under test. The various operating parameters such as temperature, voltage, frequency of operation or test pattern being applied can be independently changed on one device without affecting the operating parameters of the other devices. Thus, e.g., the amount of cooling or heating applied to one device is independent of the amount of cooling or heating applied to another device. In addition, the testing being done on each device may be independently controlled. Thus, a test can be changed on one of the devices under test without affecting the tests being run on any of the other devices. Similarly, the voltage and frequency of operation can be controlled independently to allow for changes to the voltage and/or frequency of one device without affecting that parameters on tests being run on other devices.

In one embodiment, the invention provides an integrated circuit tester that includes a plurality of test positions and a plurality of independently controllable temperature control devices associated with respective ones of the test positions, for controlling a temperature of a device under test at a respective one of the test positions. Each temperature control device is controlled without affecting operation of the other temperature control devices. Thus, cooling to one device can be increased while the testing temperature of the other devices remain constant. In an embodiment, in addition, the operating frequency of each of the devices under test is independently controllable. In addition, the integrated circuit tester may also include a plurality of independently controllable voltage regulator circuits associated with respective ones of the test positions. Each of the voltage regulator circuits supplies a controllable voltage to a respective one of the devices under test. In addition, the integrated circuit tester may also be capable of changing tests being run on one device under test independently of tests being run on other devices under test. Thus, one device can be running a built in self test while another device may be being tested with random scan patterns.

In another embodiment the invention provides a burn-in tester that includes a plurality of test stations wherein the burn-in tester is operable to independently control temperature of each device under test at each test station. In an embodiment, the burn-in tester includes multiple cooling devices per station.

In another embodiment the invention provides a method of testing a plurality of integrated circuits that includes simultaneously testing the integrated circuits at a respective plurality of test positions; and independently controlling the testing temperature of each of the integrated circuits being tested at respective ones of the test positions. The method may further include independently controlling the operating frequency of each of the integrated circuits, thereby allowing the integrated circuits to be simultaneously tested at different frequencies. The method may further include independently controlling the voltage being supplied to the integrated circuits being tested, thereby allowing the integrated circuits to be simultaneously tested at different voltages. The method may further include changing a test running on one of the integrated circuits without affecting tests being run on others of the integrated circuits.

### BRIEF DESCRIPTION OF THE DRAWINGS

The present invention may be better understood, and its numerous objects, features, and advantages made apparent to those skilled in the art by referencing the accompanying drawings wherein the use of the same reference symbols in different drawings indicates similar or identical items.

FIG. 1 is a high level illustration of an exemplary tester that can achieve independent control of relevant operational parameters for the device under test.

FIG. 2 illustrates the network coupling between each tray and the controller shown in FIG. 1.

FIG. 3 illustrates a block diagram of a tray containing 10 test stations utilized in the tester of FIG. 2.

FIG. 4 shows an exemplary high level block diagram of test controller 301 shown in FIG. 3.

FIGS. 5A-5C illustrate exemplary I²C port register definitions used in test controller 301.

FIG. 6A illustrates an exemplary control register for scan/debug controller 416 shown in FIG. 4.

FIG. 6B illustrates a scan read register of scan/debug controller 416 shown in FIG. 4.

FIG. 6C illustrates a scan write register of scan/debug controller 416 shown in FIG. 4.

FIG. 6D illustrates an exemplary status register in the scan/debug port controller 416.

FIG. 7 shows an exemplary high level block diagram of one portion of a tray that supports one test station.

FIG. 8 illustrates exemplary active and passive thermal control capabilities of the tester illustrated herein.

FIG. 9 illustrates an exemplary user interface for the burn-in tester.

FIG. 10 illustrates a cell host configuration dialog screen.

FIG. 11 illustrates a site host setting dialog screen.

FIG. 12 illustrates an exemplary pop-up password dialog.

FIG. 13 illustrates an exemplary maintenance dialog screen.

FIG. 14 illustrates an exemplary high level software architecture for the cell host.

FIG. 15 illustrates an overview of an exemplary test configuration structure.

FIG. 16 illustrates an exemplary logic flow diagram for API environmental methods.

FIG. 17 illustrates an exemplary object structure of the software operating on test control board 301.

### DESCRIPTION OF THE PREFERRED EMBODIMENT(S)

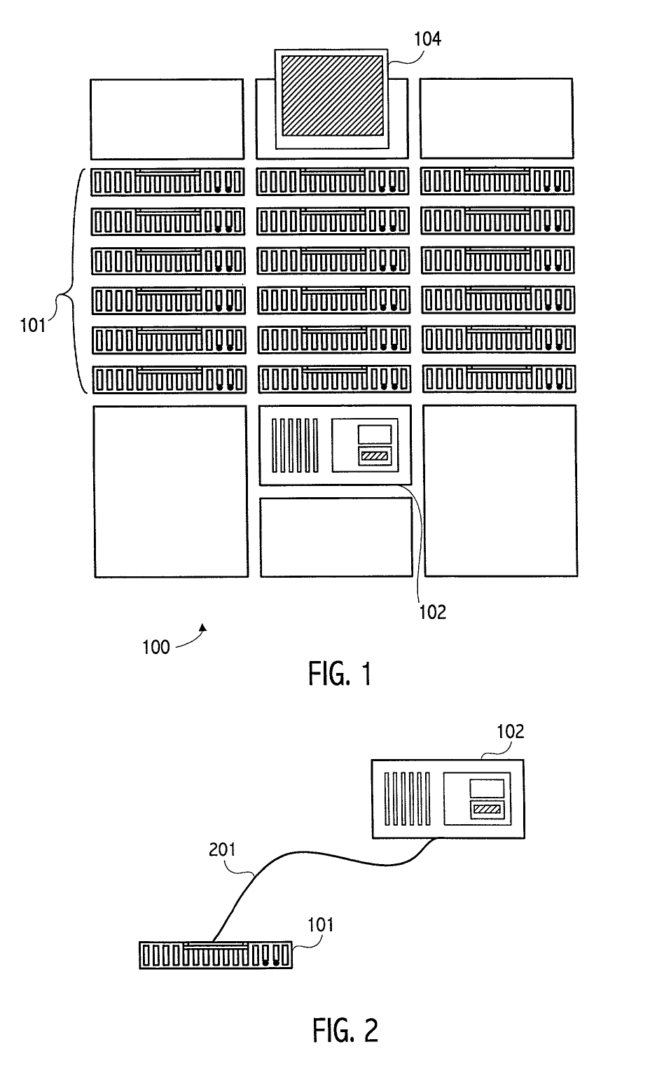

A high level illustration of an exemplary tester that can achieve independent control of the operational parameters such as temperature, clock frequency, voltage and test pattern being applied to a device under test (DUT) is illustrated in FIG. 1. Burn-in tester 100 includes a plurality of trays 101. In an exemplary embodiment, each of the trays can test up to 10 devices at one time. In the illustrated embodiment, tester 100 includes 18 trays 101 and thus can test 180 devices at one time. Overall control of the tester is provided by tester controller 102. In one embodiment, the tester shown is referred to as a cell and the test controller 102 is referred to as a cell host. Cell host 102 runs the test sequence for each device being tested in trays 101. Thus, cell host 102 controls the testing in all 18 trays. In an exemplary embodiment, as illustrated in FIG. 2, cell host 102 communicates via a network link 201 such as an Ethernet link with each tray. The cell host also provides a graphical user interface for control of tests and trays via display 104 as described further herein.

In an embodiment a site host (not shown in FIG. 1) is coupled to multiple cell hosts in order to collect test data from the individual cell hosts. The site host compresses the test data, e.g., into a zip file, and places the data onto a central server via an FTP connection over a high bandwidth connection such as an ISDN line.

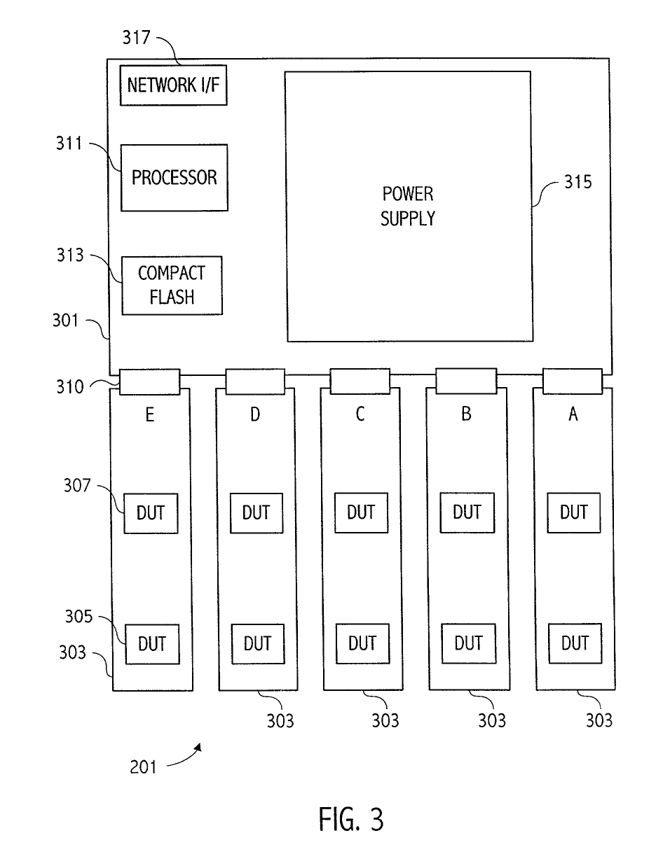

Test vectors and/or test sequences are downloaded via Ethernet link 201 to specify to each tray the tests to run on the devices being tested. As shown in FIG. 3, in one embodiment each tray includes a tray control board 301 that controls testing on five device test boards 303. The device test boards 303 are coupled to the tray control board 301 through interfaces 310 and via an Inter-IC (I²C) interface, which is a multimaster two wire serial bus. Test conditions for the device test board 303 such as temperature, voltage, and frequency are set via the bus. Test patterns that are applied to each DUT such as BIST, SCAN, or other JTAG initialed test come across interface 310. In the particular embodiment illustrated, each of the device test boards 303 includes test positions for two devices under test. Other embodiments may provide for more or fewer test positions on each device test board 303. Thus, each tray can simultaneously test 10 devices. The tray control board 301 includes a processor 311, a flash memory 313, a power supply 315 and a network interface 317. Flash memory 313 stores the tray control program. The tray control board 301 receives commands from cell host 102 (FIG. 1) and sends test results back to cell host 102. The commands may include test vectors that are processed by tray control board 301 and then supplied to the device test board and the device under test. Having a single control board and multiple test boards provides flexibility in that the tester can be reconfigured to accommodate new device test boards 303 and as the devices under test change and/or are updated. Note that the number and type of interfaces between control board 301 and device test boards may vary according to system requirements.

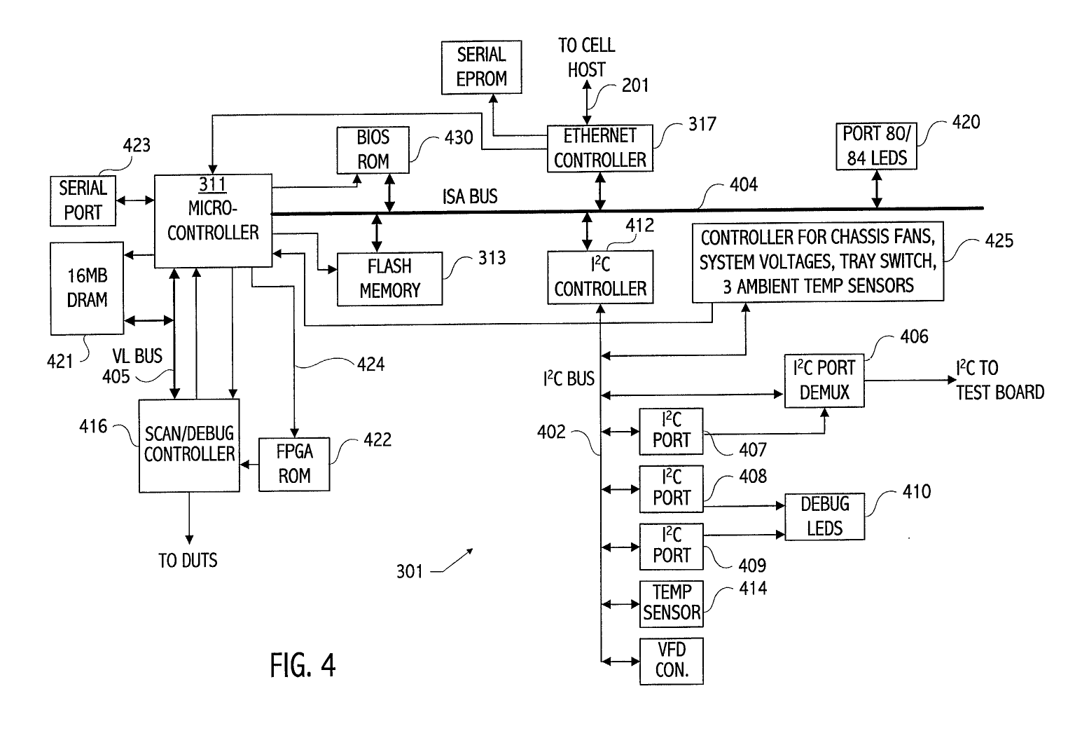

Referring to FIG. 4, the tray control board 301 is shown in greater detail. The embodiment shown in FIG. 4 is illustrative. Tray control board 301 includes Ethernet controller 317, which couples to the Ethernet link 201 that couples to the cell host. The tray control board 301 includes a local I²C bus 402. The tray control board includes multiple components that are software accessible and are described below.

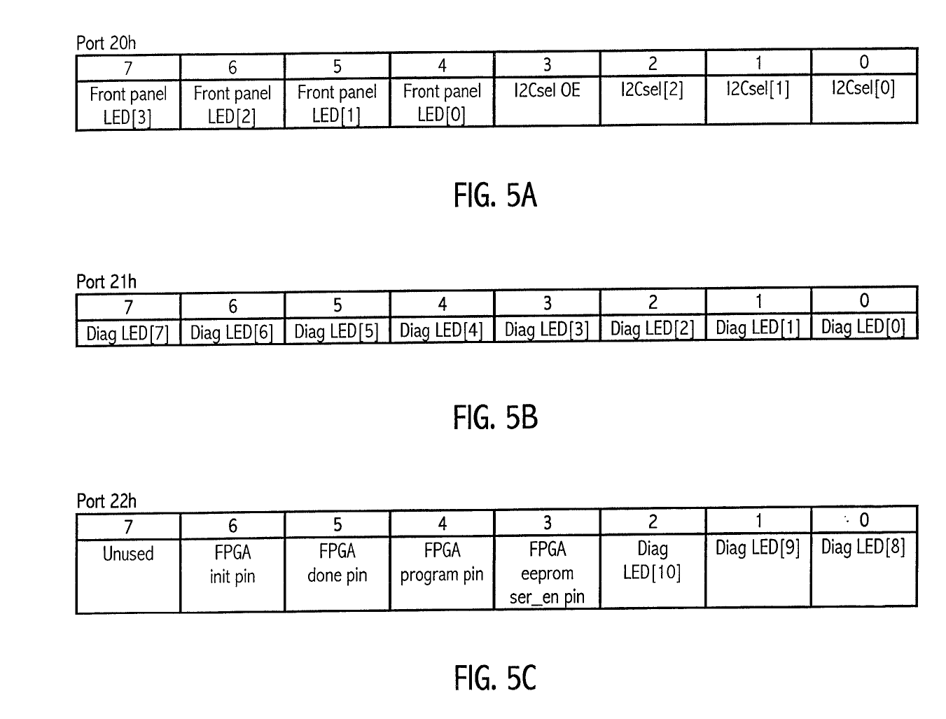

There are three I²C ports on the local test controller I²C bus 402 used to access various features described below. They are connected directly to I²C controller 412, which in one embodiment is a PCF8584 I²C controller manufactured by Phillips Corporation and which is coupled to ISA bus 404. The I²C port register definitions are shown in FIGS. 5A-5C, and in one embodiment, the ports reside at address 20h, 21h and 22h, where h represents hexadecimal. Bits (7:4) of port 20h control front panel LEDs. Bits (2:0) (I²C Sel) select which test board 301 is the target. The I²C bus is also routed to each of the individual test board 301. The I²C port de-multiplexer circuit 406 is used to select in hardware which of the tray test boards receives a particular communication. Thus, all device test boards can be accessed via a write to I²C bus 402. The three ports 407, 408, and 409 correspond to the port register definitions shown in FIGS. 5A-5C. Bit 3 of port 20h is an output enable bit for communicating with the I²C buses on the device test boards 303. I²C ports 408 and 409 control debug LEDs 410. The LEDs are controlled through ports 21h and 22h as shown in FIGS. 5B and 5C. The tray control board also includes a system monitor 425 such as a Winbond W83782D that monitors local system events. For example, it monitors DC voltages of 3.3 volts, 5 volts, 12 volts, microcontroller 311 battery backup voltage, speed of the two chassis fans and a tray switch. The system montior 425 can generate an interrupt (PIRQ 2) on the SMI pin when there is a problem detected with any of the voltage inputs, chassis fans, or when the tray is opened. A temperature sensor 414 is used to monitor the ambient temperature of the chassis and, in one embodiment, is an LM75 provided by National Semiconductor Corporation. In one embodiment the tray control board 301 provides a connection to which a debug card containing seven segment LED displays can be plugged into which can be used for debugging software and hardware problems. The port 80-/84 LEDs are shown as 420 in FIG. 4.

A scan debug port controller 416 provides the link between microcontroller 311 and the devices under test on the device test board 303. In one embodiment the scan debug port controller is a field programmable gate array (FPGA) which resides on the VL local bus 405 of microcontroller 311. Microcontroller 311 is the main controller on the tray control board 301. In one embodiment the microcontroller is an ELANSC400-66AC system controller provided by Advanced Micro Devices. In an embodiment the microcontroller 311 utilizes 16 MB DRAM 421, and 512 Kbytes of Flash memory 313. An internal serial port 423 connects to an external debug system. As shown in FIG. 4, the microcontroller provides for connection to an ISA bus 404 and a VL bus 405. In one embodiment microcontroller 311 can program the field programmable gate array 416 by programming FPGA ROM 422 through general purpose I/O pins 424.

The scan/debug controller 416 controls the scan and debug port operations for the device under test. In an exemplary embodiment, scan/debug controller 416 includes eleven 32 bit control registers, one for each of the ten individual devices under test controlled by the tray controller 301. An additional 32 bit control register provides the capability of writing to all ten control registers simultaneously. That capability is also referred to herein as gang mode operations. The control registers provide setup for the various control bits required for debug port and scan operations. Because those functions vary depending upon the device under test, the particular fields in the control registers will vary according to the capabilities and requirements of the devices that are tested by the burn-in tester.

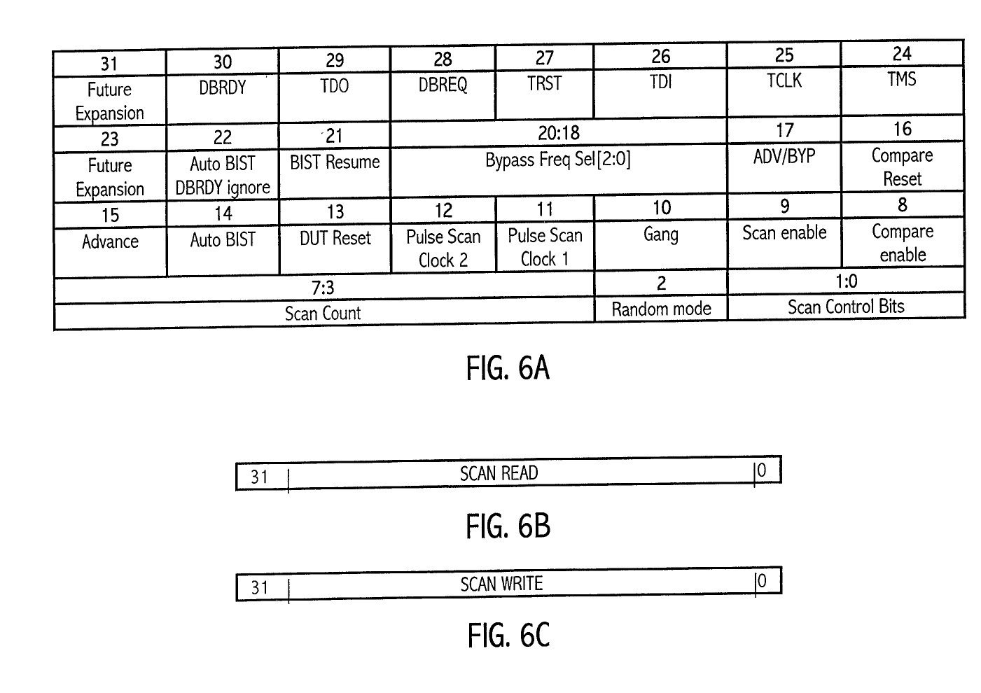

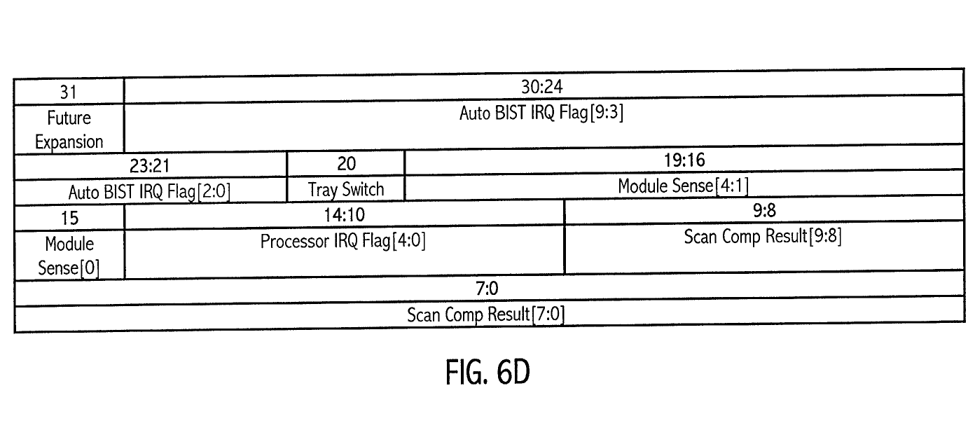

An exemplary set of control functions are shown in FIG. 6A and described below. Scan control field in bits 1:0 in one embodiment control test pins on a device under test. Certain devices may include special circuits that are sensitive to scan patterns in that scan patterns can place those circuits in an internal contention state in the device under test. The scan control bits [1:0] configure the test pins to allow such special circuits to be shielded from random scan patterns or other harmful scan patterns and also to allow selective loading of appropriate scan patterns for the special circuits. As just mentioned, in one embodiment the tester can apply random scan patterns to a device under test. Accordingly, a random mode bit (2) is provided in the control register to selectively enable the random scan mode. A count field in bits 7:3 indicates how many bits to scan in to the particular device under test. A compare enable bit (8) enables comparing of scan-in data and scan-out data. A miscompare can be programmed to cause an interrupt to the microcontroller 311. A scan enable bit (9) can be used to enable or disable scan as desired. A gang mode bit (10) specifies when the control register can be written by writing the eleventh control register. Because the gang mode bit is present in each of the control registers, a multicast capability is provided by the gang bit to write up to ten of the control register simultaneously. Thus, use of the gang control register allows the same test to be applied to one or more of the devices under test by writing only the single control register.

The Scan Clocks 1 and 2, bits 11 and 12, are used to cause the respective scan clocks to be pulsed. A reset bit (13) selectively resets the device under test. A control bit (14) selectively enables an auto Built In Self Test (BIST) mode in which BIST continually executes on the device under test. In one embodiment the device under test provides an indication when BIST has completed. On completion, the controller can detect that completion and immediately initiate a new BIST. In that way, BIST can continue running. Setting the Advance bit (bit 15) generates a single pulse on the clock selected by the ADV/BYP bit, then clears itself. The ADV/BYP bit (bit 17) defaults to 0, causing the Advance function to be routed to the bypass clock pin of the DUT. In an embodiment the bypass clock is an alternate test clock input to allow the on-board Phase Locked Loop (PLL) normally used to generate clocks to be bypassed. If the ADV/BYP bit is set to one, the bypass clock generated by scan controller 416 is routed to the bypass clock pin.. Setting the Compare Reset (bit 16) clears the scan compare error flag, then clears itself.

The Bypass Frequency Select bits (20:18) selects the frequency of the bypass clock. The BIST resume bit (21) resumes the auto BIST function after an auto BIST error condition halts the auto BIST process and clears the corresponding AutoBIST IRQ Flag bit in the status register and then clears itself.

In addition, the control register includes control bits for the JTAG signals, TMS, TCLK, TDI and TDO and TRST. These bits are used to control the scan port on the device under test. The DBREQ and DBRDY signals are handshake signals respectively requesting and acknowledging entering into a debug mode. Unique control bits should be provided to exploit the particular debug capabilities of the device under test. The test data out (TDO) bits and DBRDY bits are from the DUTs. Note that the particular control bits described in relation to FIG. 6A are exemplary only, and as stated above, will vary depending upon, e.g., the capabilities of the device under test and the particular tests that are desired to be run on the burn-in tester.

In addition to the control registers, the scan debug controller 416 has a scan read and a scan write data register as shown in FIGS. 6B and 6 C, for each DUT. The scan read data is data scanned out of the device under test and the scan write data register is data to be scanned into the device under test.

The scan/debug controller 416 also includes a status register shown in FIG. 6D. The status register provides such status information as scan compare results (bits [9:0]), one bit for each of the devices under test, and interrupt bits [14:10] from the device test boards. Each bit in a module sense bit field (bits 19:15) indicate whether a device test board is connected to the tray control board in a corresponding slot. A tray switch bit (20) indicating whether the tray in which the test control board 301 and device test boards 303 reside, has an open lid. Bits 30:21 indicate which of the ten DUTs had an autoBIST error.

In addition to particular control bits that are used to control each of the devices under lest, general purpose control registers provide for enabling of interrupts, control of power, including power-down of all test modules simultaneously, control of clocks, and reset capability of the system controller and the I²C controller. Note that some devices under test, particularly microprocessors have the capability to multiply a received clock according to software or pin programmable clock multipliers. In such an embodiment, appropriate control is provided to support such capability.

The cell host supplies the particular test through the Ethernet controller to microcontroller 311, which then writes to the appropriate control register in the scan/debug port controller 416 to cause the test to be applied to the DUT. The tests supplied by the cell host specify all the information that is required for the tray control board 301 to cause the test to be run on devices under test on the device test boards 303. Some test parameters may be set up via the I²C bus. The test information specifies voltage levels, frequency levels, the type of test to be run, for example, whether BIST is to be run or a scan test is to be run. And if a scan test is to be run, the scan patterns are provided through Ethernet controller 317 over ISA bus 404 to microcontroller 311, and subsequently to the scan write registers in scan/debug port controller 416. The clock, voltage and cooling control information is supplied in the embodiment described over the I²C bus to the device test boards. Thus, the instructions from the cell host may specify a voltage level for the device under test. That information is communicated to the microcontroller 311, which then writes the appropriate information via the I²C bus to the device test module through I²C port 406.

An exemplary burn-in tester according to an embodiment of the invention meets the following electrical capabilities. Each device under power is assumed to be capable of 1-33 watts of power consumption that includes 1-15 amps at 1.5-2.2 volts. The clock that is supplied to the devices under test ranges from 1-200 MHz. In an exemplary embodiment, the burn-in tester attempts to achieve more than 95 percent node toggle coverage. The burn-in test patterns that are applied to the device under test includes built-in self-test (BIST) capability in the device under test. That BIST capability may include, e.g., memory tests for memory located in the device under test. As previously mentioned, the burn-in test patterns may also include random serial scans. In addition to random serial scans, scan patterns from production testing can be adapted to run on the burn-in tester. Test patterns may also include functional testing as well. For example, if a microprocessor is the device under test, the processor may execute code as a functional test of the device. That may be accomplished by loading cache memory via a scan interface such as a JTAG port or other appropriate debug interface.

While the tests are running, the burn-in tester monitors whether the tests complete without failure. Depending on the type of test pattern being applied, that can be determined from pass/fail signal supplied by the device under test or by monitoring an internal register via a scan interface or monitoring a signal provided by the DUT. A test may also require a comparison of scan data scanned out of the device under test to expected results. It is also desirable for the burn-in tester to log data indicative of the tests run on the device under test. Such test data typically includes the date, time, and event, including any failures, along with sufficient information to identify the device under test. Such information may include lot, test position, along with tester information such as serial number of the test control boards and device test boards as well as revision numbers for e.g., the control software.

Because of the large number of transistors and high leakage current typical in state of the art devices, the burn-in tester in an embodiment provides both external heat for low leakage parts and cooling to stabilize high leakage parts. In a preferred embodiment, the burn-in tester provides active feedback on a desired temperature for testing, e.g., to set the operating temperature for testing at 130° C. In addition, there is preferably temperature monitoring. As described further herein, the thermal requirements can require both a Peltier device and a fan at each of the test positions in the tester. Because of the variations in power dissipated at temperatures involved in the testing, it may be preferable to have a direct contact thermal solution. Use of an active cooling device, e.g., a Peltier device, ensures that the burn-in tester has programmable thermal control over individual DUTs. The burn-in tester also preferably provides a mechanism that allows quick, easy access to change the DUTs.

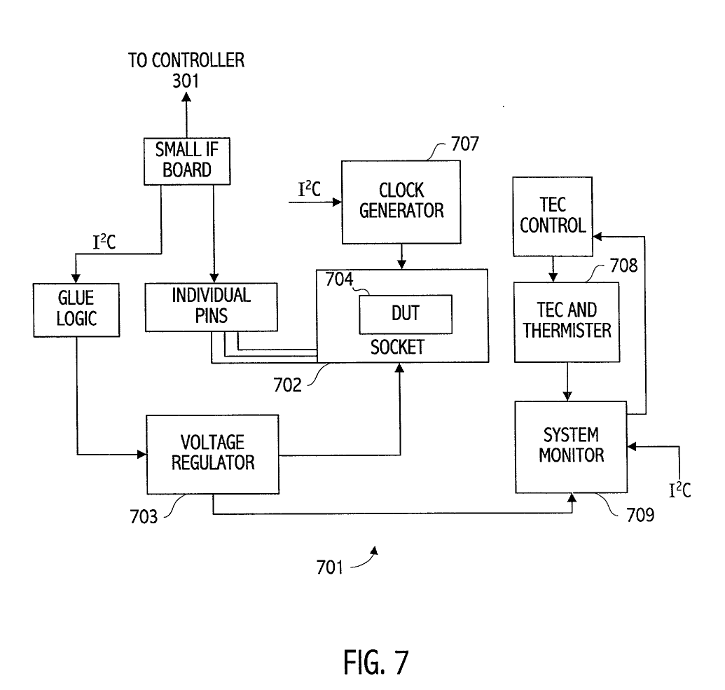

An exemplary high-level block diagram of one portion 701 of a device test board 303 is shown in FIG. 7. The one portion 701 supports one of the DUTs, e.g., 305, shown in FIG. 3. The illustrated portion in FIG. 7 includes a socket 702 for receiving the device under test 704. In one embodiment of the invention, the device under test is a microprocessor. For ease of wiring the test board in one embodiment, many of the processor pins are not connected. Only those pins that are required to implement the required burn-in tests are connected. In other embodiments, all of the pins of the device under test may be connected. The portion 701 of device test board 303 also includes a voltage regulator 703 supplying programmable voltage to the device under test and a clock generator 707 supplying programmable clocks to the device under test. In an embodiment, programmable clock multiplier values are supplied to the processor as another control mechanism for the frequency of the microprocessor clocks. Cooling devices are provided to cool the device under test. A fan (not shown) can be controlled via a system monitor 709. System monitor 709, which may be, e.g., a Winbond H/W Monitoring IC W83782D, available from Winbond Electronics Corp., can also be used to control the voltage regulator, monitor temperature and provide appropriate fan control signals. In addition to the fan, the illustrated embodiment includes a thermoelectric cooler (TEC) device 708 that can also be controlled via system monitor 709. The voltage being applied to the TEC can be changed to regulate the amount of heating or cooling. In an embodiment, the mode of TEC operations can be switched between off and fall cool to achieve better thermal stabilization. In another embodiment, the TEC can be switched from full heat to full cool mode.

Various status and control information may be communicated to and from the various functions described in FIG. 5 using an I²C bus. Other serial or parallel buses may also be used according to system requirements. In addition, appropriate logic may be used to translate from the I²C bus to another data format when necessary.

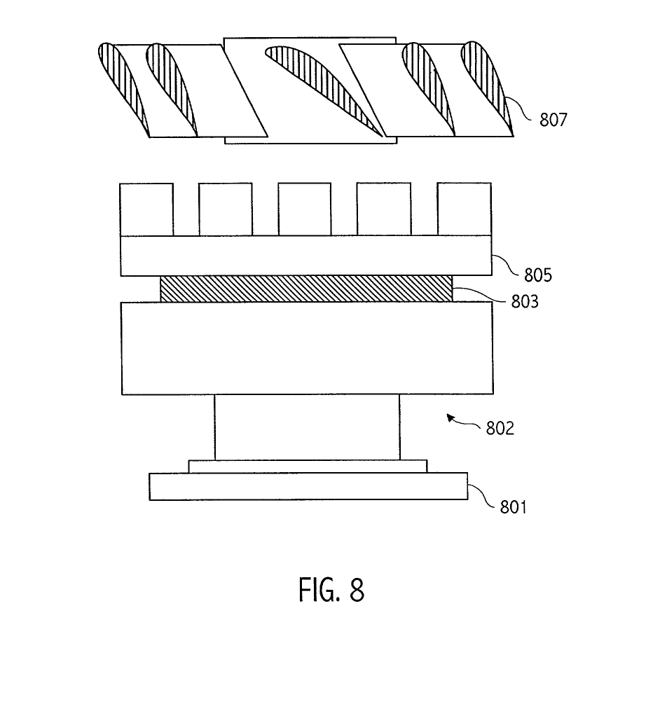

Exemplary active and passive thermal control capabilities are illustrated in FIG. 8. Device under test 801 is coupled via thermal shunt 802 to a thermoelectric device (TEC) 803. TEC 803 is activated to provide cooling to the device under test. In addition heatsink 805 is coupled to draw heat away from DUT 801 and TEC 803. Fan 807 provides further cooling capability.

In one embodiment, a temperature sensor, e.g., embedded in a heat sink is used to determine the temperature of the device under test. In other embodiments, the device under test may itself provide a temperature sensor that can be read by an external device such as system monitoring chip 709. Because two devices are tested on each board 303 in the illustrated embodiment, the logic described in FIG. 7 is duplicated to the extent necessary to provide independent control over each device under test. While the control may be completely duplicated, lesser amounts of independent control may still be sufficient. For example, clocks may be supplied commonly to both devices under test. That is in part because clock control unique to a DUT can be achieved using clock multiplier values provided to a microprocessor being tested.

The tray control board 301 individually controls each of the trays and each of the devices on the individual test boards. The status on the temperature of each DUT is fed back to the tray control board 301 and subsequently back to the cell host. Software running in the cell host can check the temperature at each station at a programmable interval to monitor temperature stability. The cell host can, if necessary to achieve stability, request an appropriate combination of a different test sequence, voltage, frequency, or additional cooling capability, e.g., turning on both the fan and TEC for a greater portion of the testing to try and achieve thermal stability as described more fully herein.

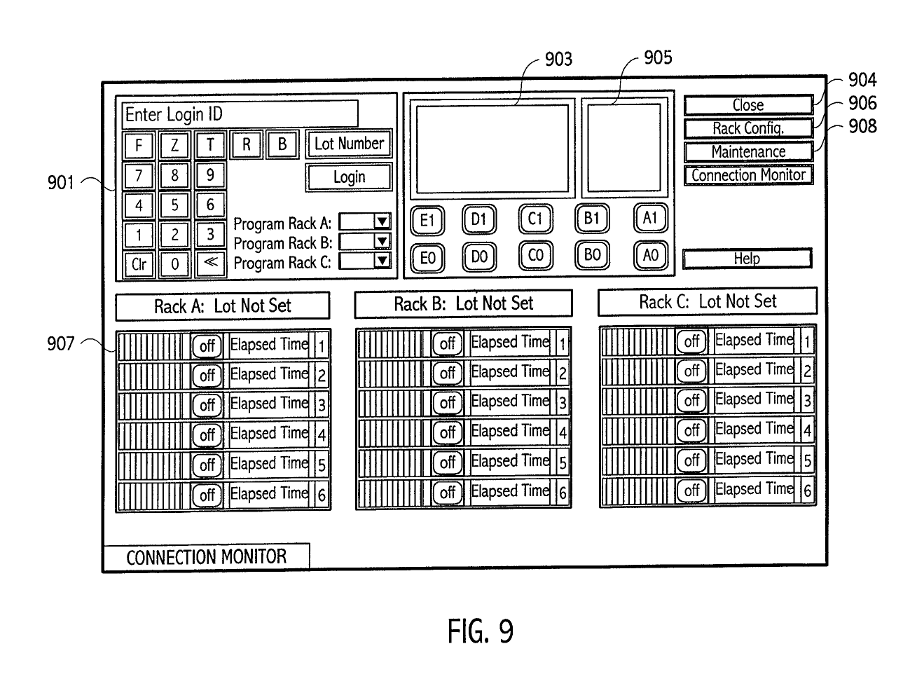

As previously described with relation to FIG. 1, an interface is provided through display 104 for the cell host operator to utilize the exemplary tester 100. Referring to FIG. 9, the operator interface contains all the controls that the test operator needs to utilize the tester.

The control pad 901 is utilized by the operator to enter a logon ID, a lot number, and to select the device ID. The status window 903 provides tray status information. In addition a CPU status window, CPU buttons, and the maintenance button are provided. The racks (rack A, rack B and rack C) correspond to the hardware racks shown in FIG. 1 and hold the trays. The trays in the main object show run time status, alerts, starts and stops of testing, and shows elapsed time and remaining time.

A dynamic add tray window will be displayed when a tray, whose IP address has not already been listed in the IP list tries to connect to the cell host. That window contains three lists of trays, one list for each rack. The engineer who adds the tray will be prompted to select a location for the new tray to be added (i.e., in which a specific rack in which sequential location). When a new tray is added, a version check will be done on the version of the embedded software in the tray. The version that is returned needs to be the expected revision or greater, otherwise a message box will indicate software needs updating.

A number of buttons in the user interface are password protected. The password protection segregates engineering activity, such as providing a new test, from actual testing activity. For example, the close button, when activated, prompts for a password before allowing the closing of the cell host. The rack configuration button 906 is a password-protected button that allows software updates and other configurable parameters to be changed per cell host. The maintenance button 908 is password protected and pops up the maintenance dialog when pushed.

During burn-in, the lot number is an important information component of the burn-in process. The test start button will not work, i.e., testing does not start without a lot number. After entering the lot number, the operator presses the lot number button. The operator is then prompted to select the racks that contain this lot, which is done by pressing the button on top of each rack, i.e., “Rack A” “Rack B” or “Rack C”.

The “Program Rack (A, B, or C)” field provides for selection of the type of the device that will be inserted into the racks for burn-in. That identification is used to look up the names of the test configuration file that will be used to perform the testing.

The tray status area 905 displays information about the tray's general status. The type of information that is displayed can include rack number, tray number, tray IP, CPU pass/fail/empty/not active state for all ten devices under test in that particular tray. The CPU status window in status window 903 provides detailed status information for the selected device under test. In order to show information in that status box, the operator selects a specific CPU after selecting the specific tray. The data that will be displayed for this selected CPU mimics the data that is being written to a status file. Displayed data thus will be a snapshot of the data to be logged before the tray button is pressed.

The tray button 907 is used to indicate alert information to the user and allow the operator to select which tray to get detailed status information. The tray button 907 can color encode information. Thus, one color can be used to indicate normal operation. Another color, such as red, can indicate that one or more of the processors have failed during a particular burn-in cycle. Another color can indicate that the tray is ready for unloading. Another indication can be used to indicate that the tray has been disabled.

A start/stop button, shown as the “Off” button in FIG. 9, starts the testing of the parts in the tray. Once the button has been pressed, the text on the button changes to stop and the button color will turn to, e.g., red to indicate the stop function. Pressing the button again causes the testing to stop, the buttons turn back to green and the text to “start.” In addition, a tray may be pulled out. When that happens, a tray switch triggers and testing is paused. If the tray is pushed back in, the testing will continue. The operator presses the stop button and testing will be terminated and the button will return to the start state. The timer display shows the elapsed time of testing.

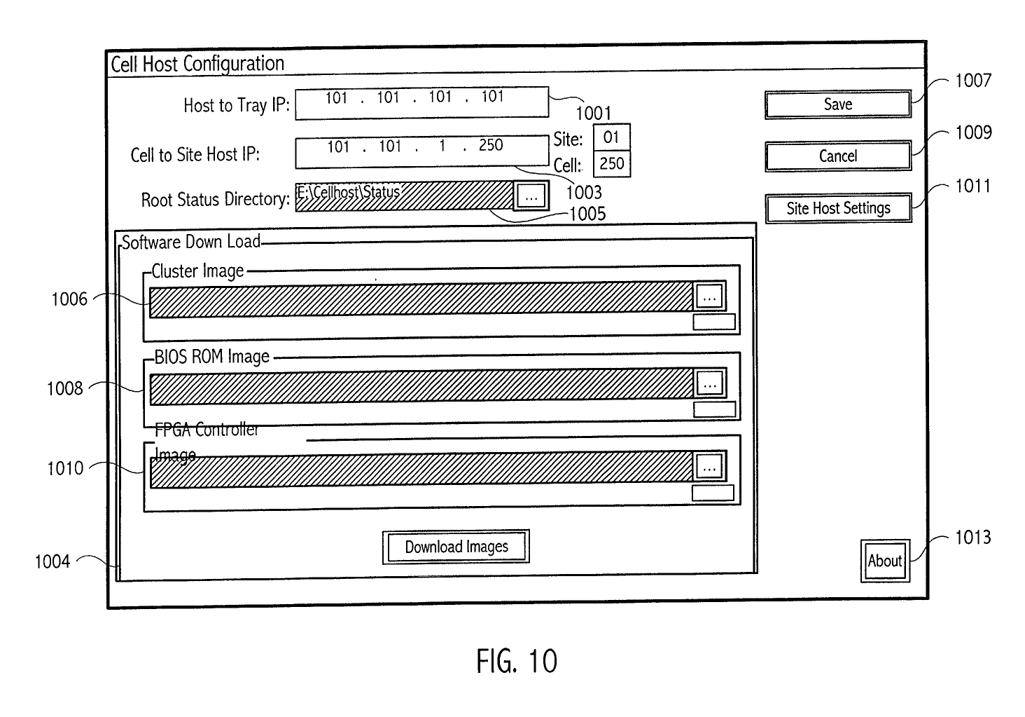

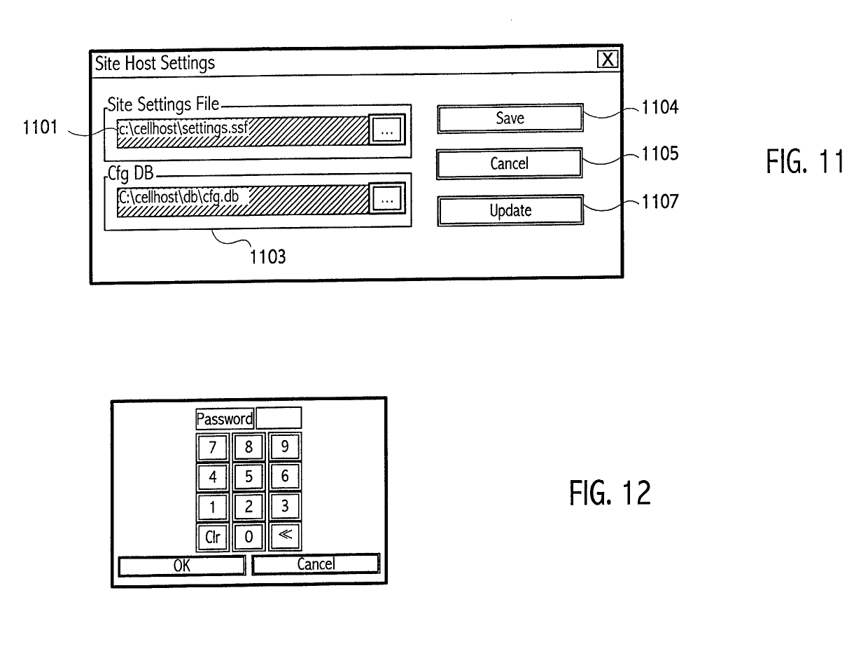

Referring to FIG. 10, a cell host configuration dialog is illustrated. The cell host configuration dialog is accessed via the password-protected button 906 labeled configuration in FIG. 9. That dialog allows engineers to change the settings of the cell host that point to different databases and other data files. Pressing buttons that are password protected in the cell host dialog, causes a popup password window such as shown in FIG. 12. That window will stay up until the correct password is input. Referring again to FIG. 10, the host to tray IP field 1001 is an IP entry field giving the internet protocol address that the cell host uses to talk to the trays. The cell-to-site host IP field 1003 is also an IP entry field that defines the IP that the cell host should use to connect to the site host. The root status directory 1005 designates the local directory where the status data files are stored.

The software download section 1004 provides the ability to update the embedded software on the test control board. There are three separate pieces of software that can be updated. The first one is the “cluster” program which is the main control program for control board 301 and is loaded into flash memory 313 (see FIG. 4). The location of the image can be specified in the cluster image field 1006. The second portion of software that can be loaded is BIOS ROM 430 shown in FIG. 4, which can be specified in BIOS ROM image 1008. The BIOS ROM is used to boot up the control board 301. The last piece of software that can be updated is software defining the functions for the scan debug controller 416, which can be specified in field 1010.

The save button 1007 saves the settings that have been entered or changed on the cell host configuration window. The cancel button 1009 ignores any changes that have made it to the entry fields on the cell host configuration window and closes the window. The site host settings button 1011 pops up a window that allows additional configurability to the cell host. Specifically, it allows the pointers to the site host information to be altered so that the cell can be severed from communicating with the site host. Referring to FIG. 11, the site settings dialog is illustrated. The site setting file field 1101 specifies the name of the site settings file. The cfg.db field 1103 provides the path to the configuration database that contains the list of test configuration files and what device identifications map to the test configuration files. The save button 1104 saves the data that was changed by the engineer. The cancel 1105 button ignores the changes that the engineer may have made and the update button causes the site setting and configuration files to be updated and their contents registered.

Referring again to FIG. 10, the about button 1013 pops up an about box providing the version information for the cell host program. The site host settings dialog is accessed via the password protected button 1011 labeled site settings on the configuration dialog shown in FIG. 10. The site setting's configuration allows engineers to change the names of the files that the cell host uses to configure its communications with the site host.

In addition new tests can be added by an engineer. In an embodiment, a dialog pops up that allows an engineer to install a new test into the cell host. Use of the dialog generates the needed registry entries for the test to be used. The dialog includes a simple file selection edit field that allows the engineer to point to the new file/test to be added. An add button in the dialog can be used once the file/test has been selected.

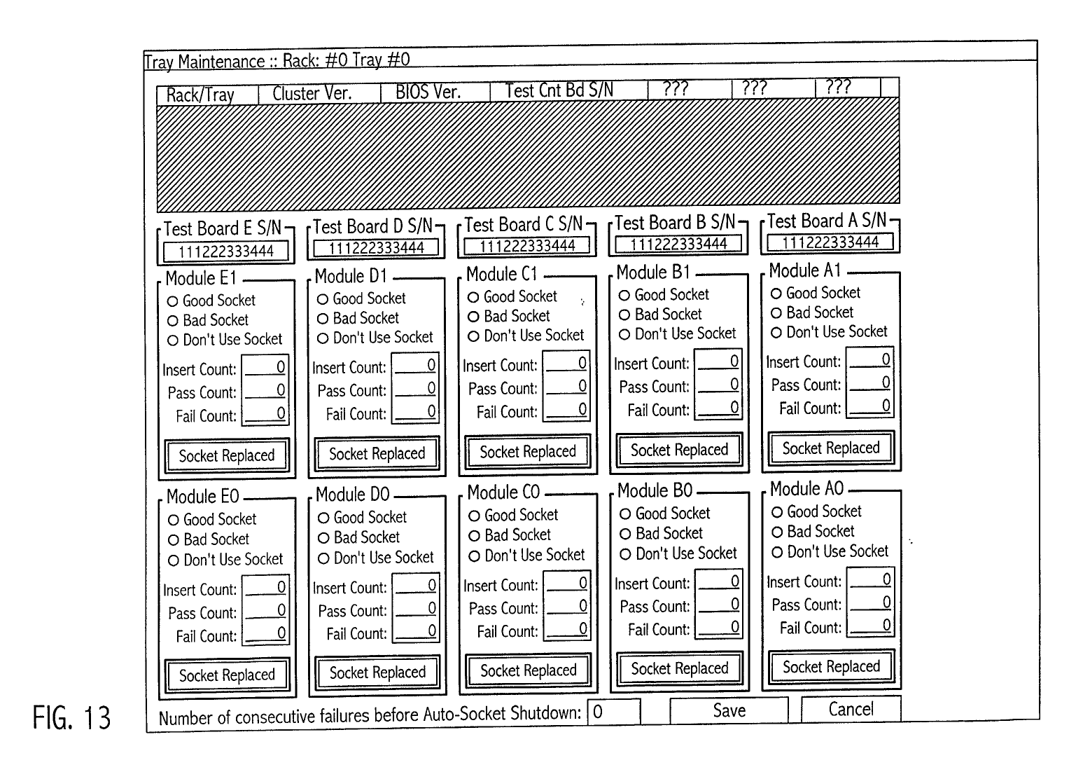

Referring to FIG. 13 an exemplary maintenance window is shown. The maintenance window is accessed via the password protected maintenance button. That window allows an engineer to view the maintenance statistics, as well as reset the settings after a socket or individual test board has been replaced. In addition, whole trays can be marked as bad and later remarked as good. Note that if a new tray is inserted into the position of where a bad tray was indicated, the new tray position will automatically be marked as good.

A tray maintenance file can store maintenance statistical information for each tray that exists within a cell. The type of information that is tracked per tray includes the cell number, the rack number, the tray number, the last update, the cell host version, the cluster version, the BIOSROM version, the IP address, the number of fails, passes, inserts, powers, auto shutdowns, manual shutdowns, socket state.

The user interface thus allows tests that have been configured for a particular device under test to be applied by an operator of the tester to the devices under test. The various screen shots shown in FIGS. 9-13 are exemplary only. The type of user interface is dependent on system design and capabilities.

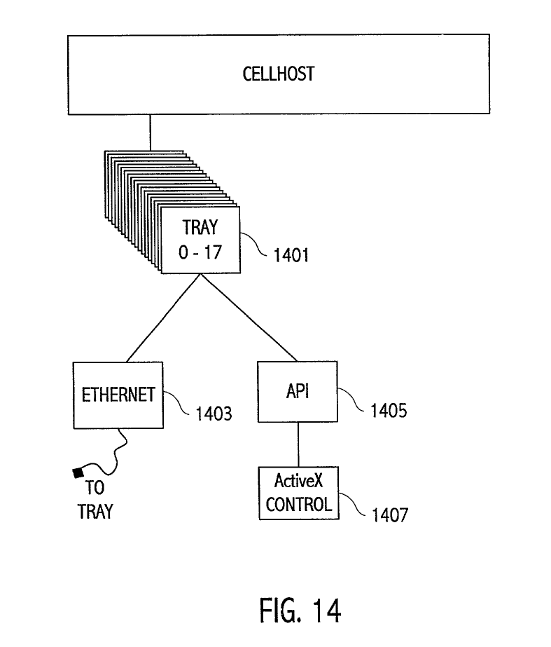

An exemplary high level software structure for the cell host is illustrated in FIG. 14. The major objects of an illustrative cell host includes a tray object 1401 for each tray controlled by the cell host. A separate Ethernet object 1403 is instantiated for each tray object 1401 so that each tray object can independently communicate with its corresponding tray. In addition each tray has an Application Programming Interface (API) object 1405 and ActiveX controls 1407 defining the tests that can be run. The API object 1405 is used to send commands down to the test control board to perform testing on devices on the device test boards.

The cell host software communicates with the trays via a rack port, which is accessed through Ethernet object 1403 in FIG. 14. The cell host has one thread listening for incoming test board connections. When a connection is requested, it will spawn a thread to handle the actual request and the original request will continue to listen for more incoming connections. The site host operates in a similar fashion to the cell host in that it has a single listening thread and spawns multiple threads to handle incoming requests from cell hosts. Each cell host requests a connection to send its data to the site host after each burn-in period has completed.

As shown in FIG. 14, a tray thread is created for each tray that populates a rack. Testing is accomplished by writing a test program that is loaded during run time based on the test operator's selection of device type through the user interface illustrated in FIG. 9. In one embodiment, the test program is generated and compiled using Visual C++. Providing a compiled test program has advantages in that the test program is free from potentially being modified by unauthorized people. In addition, the program that was released cannot be modified at run time or at the cell host. Further, better performance is achieved by running compiled code as compared to running interpreted code because the interpretation step is already completed. Thus, the commands for executing the test can be sent down to the tray immediately. The tests are provided through an application programming interface (API), which in an embodiment, are implemented with ActiveX controls using component object module (COM) technology from Microsoft Corporation.

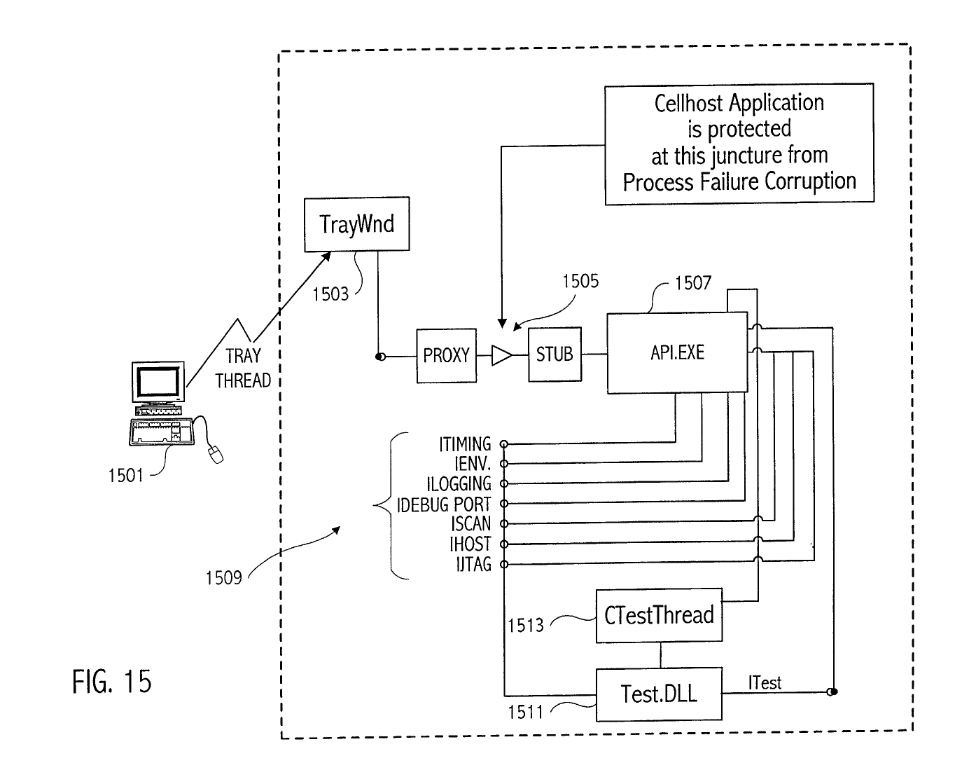

Referring to FIG. 15, an overview of the test configuration is shown. Each cell host includes a tray window object TrayWnd 1503 that interfaces to the APIs 1507. Note that FIG. 14 shows Tray 1401 as a graphical representation of TrayWnd 1503, which is an actual code object. Also, API 1507 is the implementation of the logical definition API 1405. The cell host application is protected at 1505 from process failure corruption. That means that the tray window thread remains running even if the process dies. The APIs 1507 provide test functionality through interfaces 1509, the test functionality residing in dynamic link library (DLL) 1511, which contains a library of executable test fimctions described further herein. The class CtestThread 1513 shows that a separate test thread is kicked off for each instance of a test invoked through the interfaces. FIG. 15 shows the Itest interface separately from the other interfaces 1509 because Itest needs to be implemented by the test so that the test thread knows how to communicate with the test.

Providing test functionality through APIs is advantageous because it abstracts test functions away from the test writer. Modifications to the APIs to reflect additional test capability of DUT can be made without affecting the tests already written. There are several generic definitions that can be used with multiple ones of the API functions. For example, a MODULE-ALL definition can be used to apply the function utilizing that definition across all of the devices under test in the tray. The CPU-ALL definition applies the function on both the devices under test in a single device test board. QUERY can be passed as the out or return parameter to any functions that have such parameters.

The interfaces 1509, illustrated in FIG. 15, include timing, environment, logging, debug port, scan, host, and JTAG. Each of the interfaces shown in FIG. 15, ITming, lEnvironment, ILogging, IDebug port, IScan, IHost, and I JTAG include a variety of functions that allow a test to be written by invoking those functions. Various test functions are defined to pass tests and results to and from the various test boards. For example, tray events functions transfer unexpected packets from the tray back to the test program to signal that some kind of event has occurred in the tray. That may be due to an API event failing or a problem with the hardware being detected by the imbedded software in the test control board. A parameter is provided that points to a buffer that identifies the packet as a tray event, along with the size of the packet, the ID of the failing API, the module number, the CPU number, and the reason for the event.

A tray history function is called right after a test file is loaded. That function has a data structure passed in it that defines all of the trays environmental states. If testing is paused, a perform testing function is a main routine to which testing code is added. A terminate testing function is called by the tray in the event the operator has pressed the stop testing button. A pause testing routine is called if the operator pulls the tray out. The continue testing routine is used if the operator has pulled the tray out and then pushed it back in. It is the tests responsibility to redo the environment for the device under test so valid testing is continued and test time is not lost. The tray history function provides the environmental information. A received packet routine passes the packet through the tray into the API object. Note that exemplary functions are being described. The specific functions required will vary from tester to tester and depend on the software used to implement the APIs and the test programs, the specific capability of the tester and the devices under test.

The environmental interface, IEnv, includes a plurality of functions that are used to specify the environment in which a test is performed on a particular device under test. For example, a function is provided to set the clock frequency for one of the specified modules. In an embodiment, the function can request that the current setting of the clock frequency of the specified module be returned. A clock multiplier function sets the multiplier clock frequency for the specified module in order to specify the clock frequency for the device under test. A power supply function provides the capability to power on/off a specific module/CPU. A LED function allows the LED color for the specified CPU to be set. That LED can be used to indicate, e.g., a failed test. A reset function causes the reset pin of a specified device under test to be toggled in order to cause the device under test to reset. A voltage function sets the voltage for a specified device under test. A fan function allows the tachometer on a specified fan to be set. A temperature function provides the ability to read the values of various temperature sensors provided in the device test boards. In addition, a desired temperature set point can be passed to cause the TEC to heat or cool accordingly to try and achieve the desired set point. Various other functions can be provided to control the environment according to the needs of a particular system. Note that the functions described herein are exemplary and will vary according to the types of environmental parameters that the tester is designed to control.

A timing interface (ITiming) is provided in interfaces 1509, which provides a plurality of timers that can be used for timed testing tasks. Thus, for example, functions may be provided to start a timer, stop a timer, return a value of an elapsed timer, etc. Preferably, a sufficient number of timers are provided so that multiple aspects of tests can be timed simultaneously.

A log interface (ILog) is provided in interfaces 1509 that allows logging of information to an appropriate file. The functions will be unique to the type of log file that is created, e.g., based on the type of information logged. For example, a function may provide for writing a header that provides base information identifying the source of the data. An add value entry function can be provided that allows an entry to be added to a status file.

A scan interface (IScan) provides the ability to specify a scan pattern to be scanned into a specified CPU. The scan function may provide the ability to specify the pattern to scan in, as well as an expected scan out pattern.

A host interface (IHost) allows messages to be passed by a test that will appear on the user interface or other designated location so that the message can be viewed by a test operator. An error log function may also be provided that allows a message to appear.

A Joint Test Action Group (JTAG (IEEE 1149.1)) interface (IJTAG) provides the ability to interact with the JTAG interface. The functions are heavily dependent on the test capability provided through JTAG on the particular DUT. Exemplary functions may include a clock control function to provide access to clock test modes such as cycle stretching, stopping the phase locked loop (PLL) on a specific cycle or generating N clock pulses from the PLL. A ring oscillator instruction function allows testing of a ring oscillator internal to the device under test. A run automatic test pattern generation (ATPG) function configures certain pins as scan data inputs and scan data outputs. The function may also allow the DUT to be configured as a single scan chain or multiple scan chains to run ATPG patterns. In addition, functions may be provided to configure the JTAG to provide access to a manufacturing ID and control various test functions that are available. The particular fimctions will vary depending upon the type of test capabilities that are provided through the JTAG port. That will necessarily depend upon the device under test. For example, a function can be used to force all output and bidirectional pins into a high impedance state. An instruction can be used to cause the bypass register to connect to the test data input (TDI) and test data output (TDO) of the JTAG interface. Alternatively, an instruction can cause the hardware debug test data register to be connected between TDI and TDO. Additional instructions can cause various built in self test routines to be activated and/or get the result of success or failure of those routines. Other functions may be defined to put the device under test into specific states so specific tests can be performed on them. For example, the device under test may need to be initialized to a known state using a scan flush operation before a particular test can be performed.

In addition to JTAG functions, an exemplary tester also provides hardware debug tool functions which provides for certain debug capability in a processor such as the Athlon™ processor. Any such particularized debug capability can be supported by functions provided in the interfaces.

Other functions may be provided according to the needs of the particular tester. For example, a utility interface (not shown in FIG. 15) may be provided that can be used to perform utility functions on the test control boards and the device test boards. The utility functions may provide, e.g., the capability to modify software on the device test board.

When a test is sent from the cell host to the control board the test is sent in a packet with predefined fields. Those fields can then be unpacked and acted on by the control board 301. Illustrated below are the fields of an exemplary packet:

Struct Packet {

BYTE m_PacketId
BYTE m_PacketSize
BYTE m_MethodId
BYTE m_Module
BYTE m_CPU
BOOL m_ConfirmFlag
DWORD m_BufferSize

};

The PacketId defines whether the packet represents an API request, a tray event, or a Ping event. The PacketSize defines the number of bytes in the packet. The MethodID defines which specific API to call. The parameters associated with that MethodID are put into different fields of the packet structure based on the API definition. Once the packet has been sent, software operating on the test control board receives the packet, and based on the MethodID, extracts the parameters out of the packet and calls the function corresponding to the MethodID. The module field specifies the device test board and the CPU field specifies which CPU on the device test board. The ConfirmFlag indicates whether to send back confirmation on whether the API executed successfully. Data may accompany the packet in which case the BufferSize field specifies the size of accompanying data.

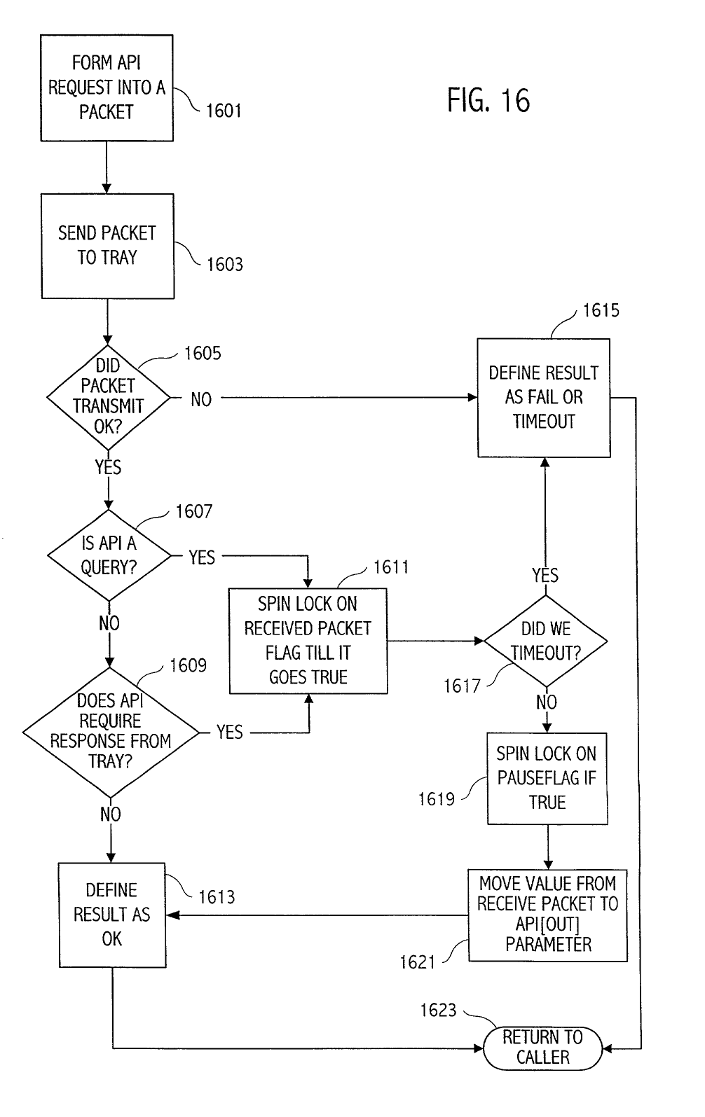

Referring to FIG. 16, an exemplary logic flow for environmental methods is shown. In 1601, an API request is organized into a packet such as the exemplary packet shown above. In 1603, the packet is sent to the tray via, e.g., an Ethernet link. In 1605, a check is made to see if the packet was sent satisfactorily. If so, then a determination is made if the API is a query in 1607, which means that a return value is expected that provides, e.g., a current temperature or voltage condition in a test board. In addition, if the API does not require a response from a tray in 1609, then Result is defined as okay indicating the API request was successful and the API returns to the caller in 1623. Result may be defined to be zero for a successful return from a function and non zero if an error occurred or if status or response information is returned. Note that if a response is required, the tray control board may determine the value of the return code in Result as shown in 1621. If the packet did not fire satisfactorily in 1605, then Result is defined as a failure or a time-out in 1615. If the API is a query or if the API requires a response from the tray, then the API waits on a received packet flag to go true in 1611. If the waiting in 1611 results in a time out, then Result is defined as a failure in 1615. If the wait did not time out in 1617, then the method waits on the pause flag, if the pause flag is true. At the end of the pause or if the pause flag is not true, in 1621 the value from the receive packet is moved to the out parameter so that the API can return the parameter, the method defines Result as ok in 1613 and returns to the caller.

On receipt of the packet by the control board, software operates to implement the testing or other action requested in the packet sent using the API. That action may involve setting and/or retrieving environmental parameters, initiating various scan, BIST or operational testing, updating software or other action that may be specified in the packet.

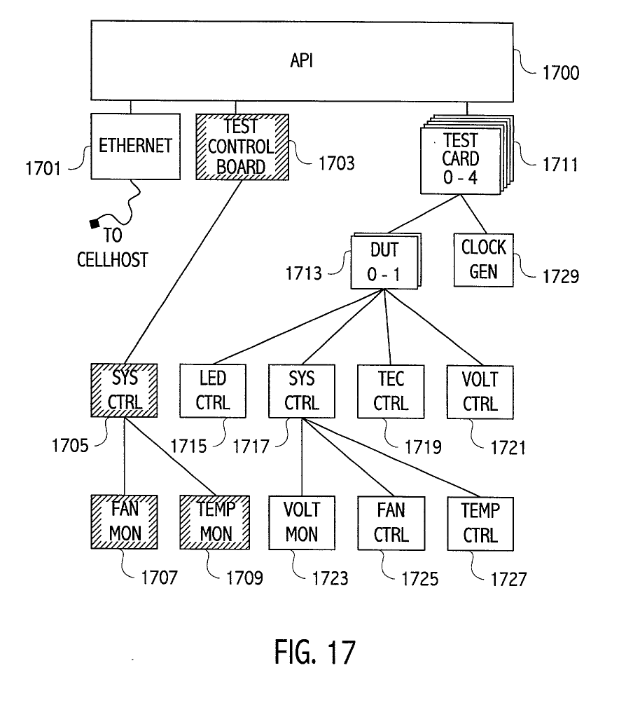

The control board 301 implements those functions using a software structure illustrated at a high level in FIG. 17. As can be seen, the software structure is closely correlated to the hardware structure. The major objects in the test control board software include an Ethernet object 1701 that provides a connection to the cellhost. API 1700 is the list of actions that the cell host and test programs use to cause the test control board software to take specific actions on a device under test or provide environmental control of the test control board or device test board. A test control board object is provided to control environmental conditions of the test control board 301 (FIG. 3). Under the test control board is a system controller 1705 that provides system control for temperature and fans on the system control board. Objects 1707 and 1709 provide fan and temperature monitoring capability, respectively. In addition, a test card object 1711 is provided for each test device board 303 controlled by the test controller card 301. Each test card in turn has two DUTs 1713. Each DUT, in turn, has objects to control LEDs 1715, a system controller object (for fans, voltage, etc.) 1717, a TEC control object 1719 and a voltage control object 1721. In addition, a voltage monitor object 1723, a fan control object 1725 and a temperature control object 1727 is provided. In one embodiment a clock object is instantiated for each test card 1711 rather than for each DUT 1713. That is because there is shared clock control capability for the two DUTs in the illustrated embodiment. In other embodiments, the clock generator object may exist for each instance of DUT 1713 reflecting fully independent control of clock generation.

One important aspect of the software architecture is that each device test board and each device on each test board has separate threads to control environmental conditions such as voltage and temperature. Thus, when a test is initiated for a particular device under test in a particular tray, that software operates independently of the software controlling the testing on other devices under test. That software and hardware structure allows for full independent control of the devices under test.

One advantage of having a burn-in tester that can provide individual control of a device under test is to ensure that thermal runaway conditions are minimized. That capability, which relies on the software and hardware architecture which allows individual control over environmental conditions for each device under test, is described in detail in the patent application entitled “STABILIZING AN INTEGRATED CIRCUIT FOR BURN-IN TESTING AT AN OTHERWISE UNSTABLE OPERATING POINT”, filed on the same day as the present application, and which names R. Mark Miller as inventor and which is incorporated by reference herein in its entirety. The approach to minimizing thermal runaway conditions is described below.

A burn-in tester operating according to an embodiment of the present invention picks an operating set point at which to test the device under test (DUT). The DUT typically remains at that set point for an extended period of time (e.g., more than 24 hours) as the burn-in tests are run. If stability is achieved at the outset of testing, the device is much more likely to remain stable during testing. As the device under test is powered up and testing is begun, its progress towards the selected set point is monitored. For example, the rate of change of temperature for the first few minutes of operation can be measured periodically, e.g., every thirty seconds, as the device approaches its set point. If the device is approaching its set point at a rate that indicates a stable approach, no action needs to be taken by the tester other than continued testing. If however, the rate of change of temperature indicates that the device is becoming or likely to become unstable because the rate of temperature change is too high, operating parameters of the device under test can be changed and the set point approached again. The high temperature characteristics of a part are typically unknown prior to burn-in testing, since previous tests are run at increasingly low temperatures.

For example, assume a rate of change is determined to be too high. In that case, the tester changes one of the operating parameters and tries to bring the device under test up to the set point for stable operation. For example, the tester may lower the frequency being supplied to the device under test. In addition to reducing frequency, other operating parameters can be varied instead of or in combination with reducing operating frequency. For instance, the gain of the thermoelectric cooler (TEC) may be increased to attempt to control the temperature as the DUT approaches the set point.

In addition, the particular type of test being run or test vectors being applied may affect power consumption and thus temperature. For example, if random patterns are being used as test vectors, a test that consumes less power, such as a memory test, can be run instead. Such a test exercises fewer circuits in the device under test and thus reduces power consumption. Finally, voltage may be reduced in an attempt to bring the DUT to a stable operating point. Voltage is typically the last parameter to change because reducing voltage also effects the burn-in reliability acceleration. In addition, voltage should not be reduced greater than the field voltage (i.e., the typical operating voltage). In fact, any combination of the above-described operating parameters can be utilized to try to bring the device to stable operation at the selected temperature set point. Thus, if lowering the frequency of the device under test fails to achieve stable operation, both lowered frequency and increased TEC gain may be used to try to approach the set point in a stable manner. If that fails to work, different tests may also be utilized. Finally, voltage may also be lowered. The attempts to approach the set point in a stable manner may continue with different combinations of operating parameters until the DUT achieves stable operation at the set point. The various hardware and software described herein is effective at providing independent control of the devices under test to achieve stable operation.

Thus, the hardware and software of a tester apparatus and method have been described, which provides for independent control of the operational and environmental parameters of the devices under test. The description of the invention set forth herein is illustrative, and is not intended to limit the scope of the invention as set forth in the following claims. Variations and modifications of the embodiments disclosed herein, may be made based on the description set forth herein, without departing from the scope and spirit of the invention as set forth in the following claims.

What is claimed is:

1. An integrated circuit tester comprising:
a plurality of test positions; and
a plurality of independently controllable temperature control devices associated with respective ones of the test positions, for controlling a temperature of a device under test at a respective one of the test positions, each temperature control device being controlled without affecting operation of remaining ones of the temperature control devices.

2. The integrated circuit tester as recited in claim 1 wherein the operating frequency of each of the devices under test is independently controllable.

3. The integrated circuit tester as recited in claim 1 further comprising:
a plurality of independently controllable voltage regulator circuits associated with respective ones of the test positions, each of the voltage regulator circuits supplying a controllable voltage to a respective one of the devices under test.

4. The integrated circuit tester as recited in claim 1 wherein the integrated circuit tester is a burn-in tester and is coupled to change tests being run on one device under test independently of tests being run on other devices under test.

5. The integrated circuit tester as recited in claim 1 wherein each of the temperature control devices is a thermoelectric cooler.

6. The integrated circuit tester as recited in claim 1 wherein the integrated circuit tester is coupled to leave unconnected multiple ones of the signal input/output pins on the device under test.

7. A burn-in tester comprising:
a plurality of test stations; and
wherein the burn-in tester is operable to independently control temperature of each device under test at each test station.

8. The burn-in tester as recited in claim 7 wherein the burn-in tester includes multiple cooling devices per station.

9. The burn-in tester as recited in claim 7 wherein the cooling devices include a thermoelectric cooler and a fan.

10. The burn-in tester as recited in claim 7 wherein the burn-in tester is further operable to independently control tests being applied to each device under test at each test position.

11. The burn-in tester as recited in claim 10 wherein the tests include at least one of automatic test pattern generation (ATPG) test patterns, functional testing, random scan patterns applied by the tester and built in self test (BIST) tests.

12. The burn-in tester as recited in claim 7 wherein the burn-in tester is further operable to independently control voltage being applied to each device under test at each test position.

13. The burn-in tester as recited in claim 10 wherein the burn-in tester is operable to independently control the operating frequency of each of the devices under test.

14. The burn-in tester as recited in claim 7 wherein the burn-in tester is further operable to independently control tests being applied to each device under test at each test position and to independently control voltage being applied to each device under test at each test position.

15. The burn-in tester as recited in claim 14 wherein the burn-in tester independently changes a frequency of operation of one device under test independently of operational frequencies of other devices under test.

16. The burn-in tester as recited in claim 7 wherein the burn-in tester includes a centralized tester controller coupled to control multiple test control boards and wherein each test control board is coupled to control multiple device test boards, each device test board containing at least one device under test.

17. The burn-in tester as recited in claim 16 wherein the test controller is coupled via a network link to each of the test control boards.

18. A method of testing a plurality of integrated circuits comprising:
simultaneously testing the integrated circuits at a respective plurality of test positions; and
independently controlling a testing temperature of each of the integrated circuits being tested at respective ones of the test positions.

19. The method as recited in claim 18 further comprising independently controlling an operating frequency of each of the integrated circuits, thereby allowing at least some of the integrated circuits to be simultaneously tested at different frequencies.

20. The method as recited in claim 19 wherein the operating frequency of the integrated circuits are controlled by supplying clock control signals indicating multiplier values for a supplied clock.

21. The method as recited in claim 18 further comprising independently controlling the voltage being supplied to the integrated circuits being tested, thereby allowing at least some of the integrated circuits to be simultaneously tested at different voltages.

22. The method as recited in claim 18 further comprising changing a test running on one of the integrated circuits without affecting tests being run on others of the integrated circuits.

23. The method as recited in claim 18 further comprising:
independently controlling a voltage being supplied to each of the integrated circuits being tested, thereby allowing at least some of the integrated circuits to be simultaneously tested at different voltages; and
independently controlling a test being applied to each of the,integrated circuits, thereby allowing at least some of the integrated circuits to be simultaneously tested with different test patterns.

24. The method as recited in claim 23 further comprising independently controlling an operating frequency of each of the integrated circuits, thereby allowing at least some of the integrated circuits to be simultaneously tested at different frequencies.

25. A testing apparatus comprising:
a plurality of test positions;
means for controlling temperature of an integrated circuit being tested in one test position independently of temperatures of other integrated circuits being tested in other of the test positions.

26. The testing apparatus as recited in claim 25 further comprising:
means for controlling voltage of an integrated circuit being tested in the one test position independently of voltages of other integrated circuits being tested in other of the test positions.

27. The testing apparatus as recited in claim 25 further comprising:
means for controlling a test being applied to an integrated circuit being tested in the one test position independently of tests being applied to other integrated circuits being tested in other of the test positions.

28. The testing apparatus as recited in claim 25 further comprising;
means for controlling frequency of an integrated circuit being tested in the one test position independently of frequency of other integrated circuits being tested in other of the test positions.
